(19) United States
(12) Patent Application Publication
(10) Pub. No.: US 2025/0203811 A1
(43) Pub. Date: Jun. 19, 2025

(54) COOLING SYSTEM AND LIQUID COOLING DEVICE

(71) Applicant: Wistron Corporation, New Taipei City (TW)

(72) Inventors: Sheng-Yen Lin, New Taipei City (TW); Yu-Chuan Wu, New Taipei City (TW); Hua Chen, New Taipei City (TW)

(73) Assignee: Wistron Corporation, New taipei City (TW)

(21) Appl. No.: 18/600,789

(22) Filed: Mar. 11, 2024

(30) Foreign Application Priority Data
Dec. 13, 2023 (TW) 112148540

(51) Int. Cl. H05K 7/20

(52) U.S. Cl. CPC H05K 7/20272; H05K 7/20263

(57) ABSTRACT

A cooling system includes an electronic device and a liquid cooling device. The liquid cooling device includes a casing, a first inlet, a first outlet, a second inlet, a second outlet, a first tank, a first pump and a heat exchanger. The first inlet is disposed on the casing and connected to the electronic device. The first outlet is disposed on the casing and connected to the electronic device. The second inlet and the second outlet are disposed on the casing. The first tank is disposed in the casing. The first pump is disposed in the casing. The heat exchanger is disposed in the casing. The first inlet, the heat exchanger, the first pump, the first tank and the first outlet form a first cooling loop. The second inlet, the heat exchanger and the second outlet form a second cooling loop.

### BACKGROUND OF THE INVENTION

### 1. Field of the Invention

The disclosure relates to a cooling system and a liquid cooling device and, more particularly, to a liquid cooling device capable of effectively reducing an amount of cooling liquid and a cooling system equipped with the liquid cooling device.

### 2. Description of the Prior Art

As the speed and performance of electronic components (e.g. central processing unit) in a server increase, more and more servers adopt a liquid cooling manner to dissipate heat from the electronic components to improve heat dissipation efficiency. In a cooling system, an amount of cooling liquid is highly related to cost. How to effectively reduce the amount of cooling liquid has become a significant design issue.

### SUMMARY OF THE INVENTION

The disclosure provides a liquid cooling device capable of effectively reducing an amount of cooling liquid and a cooling system equipped with the liquid cooling device, so as to solve the aforesaid problems.

According to an embodiment of the disclosure, a cooling system comprises an electronic device and a liquid cooling device. The liquid cooling device comprises a casing, a first inlet, a first outlet, a second inlet, a second outlet, a first tank, a first pump and a heat exchanger. The first inlet is disposed on the casing and connected to the electronic device. The first outlet is disposed on the casing and connected to the electronic device. The second inlet is disposed on the casing. The second outlet is disposed on the casing. The first tank is disposed in the casing. The first pump is disposed in the casing. The heat exchanger is disposed in the casing. The first inlet, the heat exchanger, the first pump, the first tank and the first outlet form a first cooling loop in the casing. The second inlet, the heat exchanger and the second outlet form a second cooling loop in the casing. The heat exchanger is located between the first cooling loop and the second cooling loop.

According to another embodiment of the disclosure, a liquid cooling device comprises a casing, a first inlet, a first outlet, a second inlet, a second outlet, a first tank, a first pump and a heat exchanger. The first inlet is disposed on the casing. The first outlet is disposed on the casing. The second inlet is disposed on the casing. The second outlet is disposed on the casing. The first tank is disposed in the casing. The first pump is disposed in the casing. The heat exchanger is disposed in the casing. The first inlet, the heat exchanger, the first pump, the first tank and the first outlet form a first cooling loop in the casing. The second inlet, the heat exchanger and the second outlet form a second cooling loop in the casing. The heat exchanger is located between the first cooling loop and the second cooling loop.

As mentioned in the above, the disclosure utilizes the first inlet, the heat exchanger, the first pump, the first tank and the first outlet to form the first cooling loop in the casing of the liquid cooling device, and utilizes the second inlet, the heat exchanger and the second outlet to form the second cooling loop in the casing. Accordingly, the cooling liquid in the first cooling loop may be oil, dielectric liquid or the like with higher cost, and the cooling liquid in the second cooling loop may be water or the like with lower cost. The cooling liquid in the first cooling loop exchanges heat through the heat exchanger. Thus, the cooling liquid in the first cooling loop does not need to be transported to an external cooling distribution unit through a manifold for heat exchange. Accordingly, the disclosure can save the amount of cooling liquid in the manifold and the external cooling distribution unit, such that the liquid cooling device of the disclosure can effectively reduce the amount of high-cost cooling liquid in the first cooling loop.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a cooling system according to an embodiment of the disclosure.

FIG. 2 is a perspective view illustrating a liquid cooling device shown in FIG. 1.

FIG. 3 is a schematic view illustrating a cooling system according to another embodiment of the disclosure.

FIG. 4 is a perspective view illustrating the liquid cooling device according to another embodiment of the disclosure.

### DETAILED DESCRIPTION

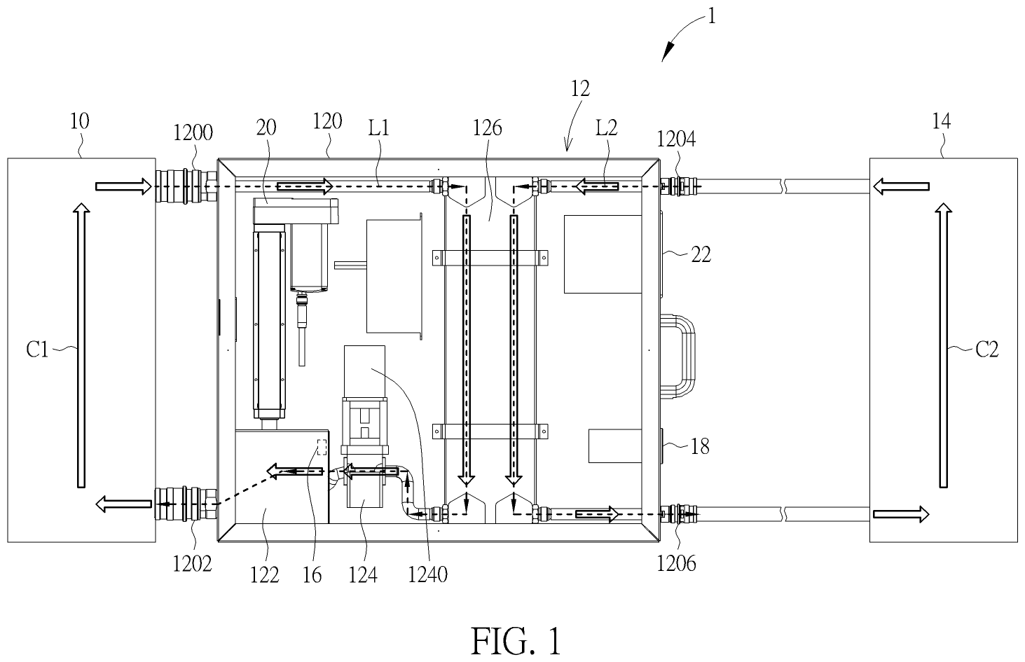

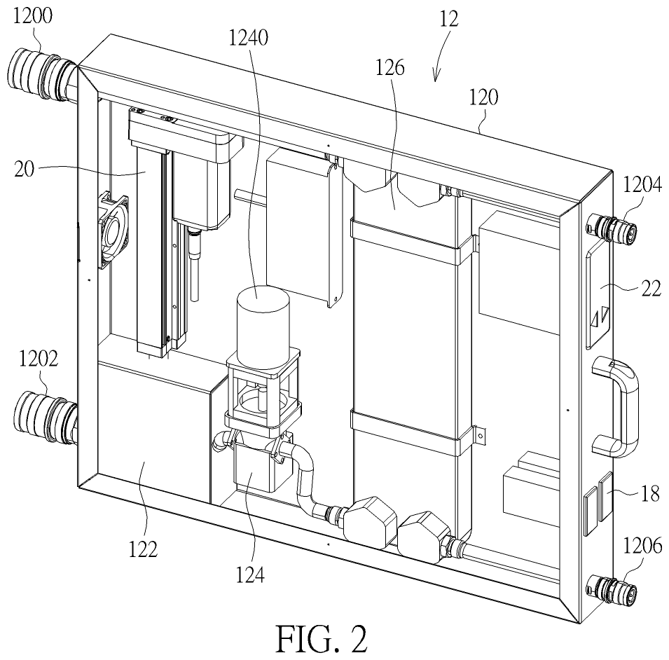

Referring to FIGS. 1 and 2, FIG. 1 is a schematic view illustrating a cooling system 1 according to an embodiment of the disclosure, and FIG. 2 is a perspective view illustrating a liquid cooling device 12 shown in FIG. 1.

As shown in FIG. 1, the cooling system 1 includes an electronic device 10, a liquid cooling device 12 and a cooling distribution unit 14. The liquid cooling device 12 is configured to transport a cooling liquid C1 to the electronic device 10 to dissipate heat from the electronic device 10. The cooling distribution unit 14 is configured to transport a cooling liquid C2 to the liquid cooling device 12 to exchange heat with the cooling liquid C1. The electronic device 10 may be a server or other electronic devices according to practical application. It should be noted that the principle of the cooling distribution unit 14 is well known by one skilled in the art, so the explanation will not be depicted herein.

The liquid cooling device 12 comprises a casing 120, a first inlet 1200, a first outlet 1202, a first tank 122, a first pump 124 and a heat exchanger 126, wherein the first tank 122, the first pump 124 and the heat exchanger 126 are disposed in the casing 120. The electronic device 10 and the cooling distribution unit 14 are located outside the casing 120. The first inlet 1200 and the first outlet 1202 are disposed on the casing 120 and connected to the electronic device 10. Furthermore, the liquid cooling device 12 further comprises a second inlet 1204 and a second outlet 1206, wherein the second inlet 1204 and the second outlet 1206 are disposed on the casing 120 and connected to the cooling distribution unit 14. In this embodiment, the first inlet 1200 and the first outlet 1202 may be located at a side of the casing 120, and the second inlet 1204 and the second outlet 1206 may be located at another side of the casing 120, but the invention is not so limited.

The first tank 122 is connected to the first outlet 1202. The first pump 124 is connected to the first tank 122. A side of the heat exchanger 126 is connected to the first pump 124 and the first inlet 1200, and another side of the heat exchanger 126 is connected to the second inlet 1204 and the second outlet 1206. In this embodiment, the heat exchanger 126 may be, but is not limited to, a plate heat exchanger.

As shown in FIG. 1, the first inlet 1200, the heat exchanger 126, the first pump 124, the first tank 122 and the first outlet 1202 communicate with each other to form a first cooling loop L1 in the casing 120. The first pump 124 may transport the cooling liquid C1 stored in the first tank 122 to the electronic device 10 through the first outlet 1202. The cooling liquid C1 that has been heat exchanged in the electronic device 10 may be transported to the heat exchanger 126 through the first inlet 1200 and cooled by the heat exchanger 126. Then, the cooled cooling liquid C1 is transported to the electronic device 10 through the first pump 124, the first tank 122 and the first outlet 1202. In other words, the cooling liquid C1 may circulate between the casing 120 of the liquid cooling device 12 and the electronic device 10 through the first cooling loop L1.

It should be noted that the relative positions and connection relationships of the heat exchanger 126, the first pump 124 and the first tank 122 may be in different arrangements and combinations, as long as the first inlet 1200, the heat exchanger 126, the first pump 124, the first tank 122 and the first outlet 1202 communicate with each other to form the first cooling loop L1 in the casing 120. For example, the first pump 124 may also be connected to the first inlet 1200.

As shown in FIG. 1, the second inlet 1204, the heat exchanger 126 and the second outlet 1206 communicate with each other to form a second cooling loop L2 in the casing 120, wherein the heat exchanger 126 is located between the first cooling loop L1 and the second cooling loop L2. The cooling distribution unit 14 may provide and transport the cooling liquid C2 to the heat exchanger 126 through the second inlet 1204, so as to exchange heat with the aforesaid cooling liquid C1. The heat-exchanged cooling liquid C2 is then transported to the cooling distribution unit 14 through the second outlet 1206 for cooling. In other words, the cooling liquid C2 may circulate between the casing 120 of the liquid cooling device 12 and the cooling distribution unit 14 through the second cooling loop L2.

In this embodiment, the cooling liquid C1 may be oil, dielectric liquid or the like with higher cost, and the cooling liquid C2 may be water or the like with lower cost. Thus, the cooling liquid C1 in the first cooling loop L1 is different from the cooling liquid C2 in the second cooling loop L2. The cooling liquid C1 in the first cooling loop L1 exchanges heat through the heat exchanger 126. Thus, the cooling liquid C1 in the first cooling loop L1 does not need to be transported to an external cooling distribution unit (different from the cooling distribution unit 14 of the disclosure) through a manifold for heat exchange. Accordingly, the disclosure can save the amount of cooling liquid C1 in the manifold and the external cooling distribution unit, such that the liquid cooling device 12 of the disclosure can effectively reduce the amount of high-cost cooling liquid C1 in the first cooling loop L1. It should be noted that the cooling liquid C2 in the cooling distribution unit 14 of the disclosure may be water or the like with lower cost, so the cooling distribution unit 14 will not increase the amount of cooling liquid C1.

As shown in FIGS. 1 and 2, the liquid cooling device 12 may further comprise a temperature sensor 16 and a temperature controller 18. The temperature sensor 16 is disposed in the first tank 122. The first pump 124 comprises a motor 1240. The temperature controller 18 is disposed on the casing 120 and coupled to the temperature sensor 16 and the motor 1240. In practical applications, the temperature controller 18 may be coupled to the temperature sensor 16 and the motor 1240 by appropriate circuit layout. The temperature sensor 16 is configured to sense a temperature of the cooling liquid C1 in the first tank 122. The temperature controller 18 is configured to respond to the temperature sensor 16 to control a rotation speed of the motor 1240 to regulate the temperature of the cooling liquid C1.

As shown in FIGS. 1 and 2, the liquid cooling device 12 may further comprise an electric cylinder 20 and a volume control panel 22. The electric cylinder 20 is connected to the first tank 122. The volume control panel 22 is disposed on the casing 120 and coupled to the electric cylinder 20. In practical applications, the volume control panel 22 may be coupled to the electric cylinder 20 by appropriate circuit layout. The volume control panel 22 is configured to control the electric cylinder 20 to regulate a liquid level of the cooling liquid C1 in the first tank 122, so as to achieve the effect of saving the cooling liquid C1.

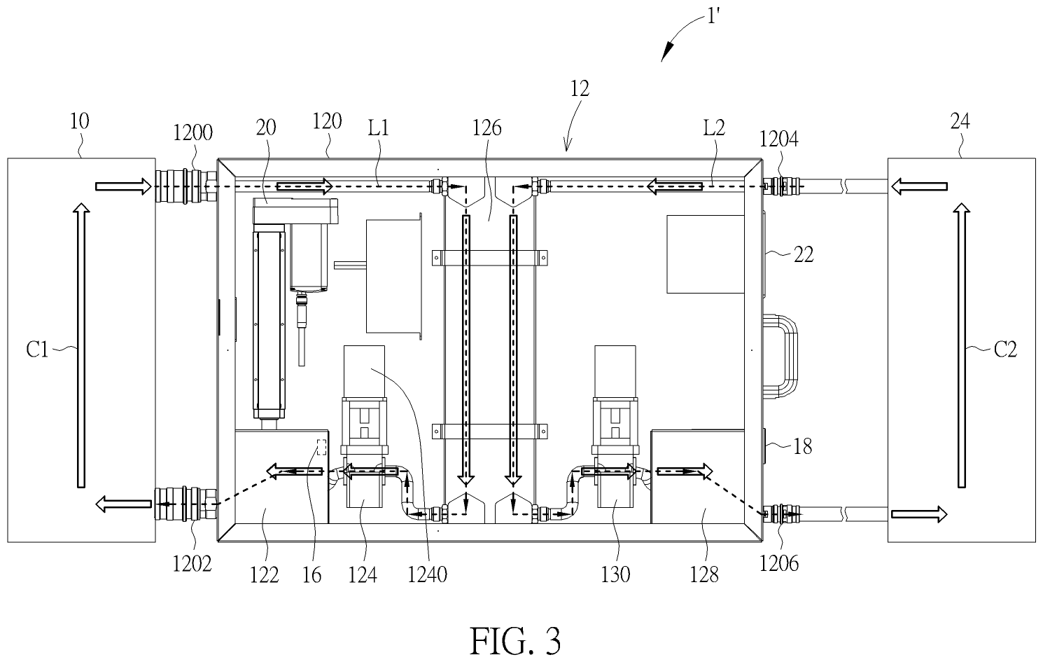

Referring to FIG. 3, FIG. 3 is a schematic view illustrating a cooling system 1′ according to another embodiment of the disclosure.

The main difference between the cooling system 1′ and the aforesaid cooling system 1 is that the liquid cooling device 12 of the cooling system 1′ further comprises a second tank 128 and a second pump 130, and the heat exchanger 126 is connected to the second pump 130 and the second inlet 1204, as shown in FIG. 3. The second tank 128 and the second pump 130 are disposed in the casing 120. The second tank 128 is connected to the second outlet 1206, and the second pump 130 is connected to the second tank 128.

Furthermore, the cooling system 1′ further comprises a liquid storage device 24 to replace the aforesaid cooling distribution unit 14. The electronic device 10 and the liquid storage device 24 are located outside the casing 120. The second inlet 1204 and the second outlet 1206 are connected to the liquid storage device 24. In this embodiment, the liquid storage device 24 may be a device that stores the cooling liquid C2 (e.g. a building water tower). The cooling liquid C2 of the liquid storage device 24 may be transported to the liquid cooling device 12 to exchange heat with the cooling liquid C1.

As shown in FIG. 3, the second inlet 1204, the heat exchanger 126, the second pump 130, the second tank 128 and the second outlet 1206 communicate with each other to form a second cooling loop L2 in the casing 120, wherein the heat exchanger 126 is located between the first cooling loop L1 and the second cooling loop L2. The second pump 130 may transport the cooling liquid C2 stored in the liquid storage device 24 to the heat exchanger 126 through the second inlet 1204. The cooling liquid C2 after heat exchange with the cooling liquid C1 may be transported to the liquid storage device 24 through the second pump 130, the second tank 128 and the second outlet 1206. In other words, the cooling liquid C2 may circulate between the casing 120 of the liquid cooling device 12 and the liquid storage device 24 through the second cooling loop L2.

It should be noted that the relative positions and connection relationships of the heat exchanger 126, the first pump 124 and the first tank 122 may be in different arrangements and combinations, as long as the first inlet 1200, the heat exchanger 126, the first pump 124, the first tank 122 and the first outlet 1202 communicate with each other to form the first cooling loop L1 in the casing 120. Furthermore, the relative positions and connection relationships of the heat exchanger 126, the second pump 130 and the second tank 128 may be in different arrangements and combinations, as long as the second inlet 1204, the heat exchanger 126, the second pump 130, the second tank 128 and the second outlet 1206 communicate with each other to form the second cooling loop L2 in the casing 120. For example, the first pump 124 may also be connected to the first inlet 1200, and the second pump 130 may also be connected to the second inlet 1204.

In this embodiment, the cooling liquid C1 may be oil, dielectric liquid or the like with higher cost, and the cooling liquid C2 may be water or the like with lower cost. Thus, the cooling liquid C1 in the first cooling loop L1 is different from the cooling liquid C2 in the second cooling loop L2. The cooling liquid C1 in the first cooling loop L1 exchanges heat through the heat exchanger 126. Thus, the cooling liquid C1 in the first cooling loop L1 does not need to be transported to an external cooling distribution unit through a manifold for heat exchange. Accordingly, the disclosure can save the amount of cooling liquid C1 in the manifold and the external cooling distribution unit, such that the liquid cooling device 12 of the disclosure can effectively reduce the amount of high-cost cooling liquid C1 in the first cooling loop L1.

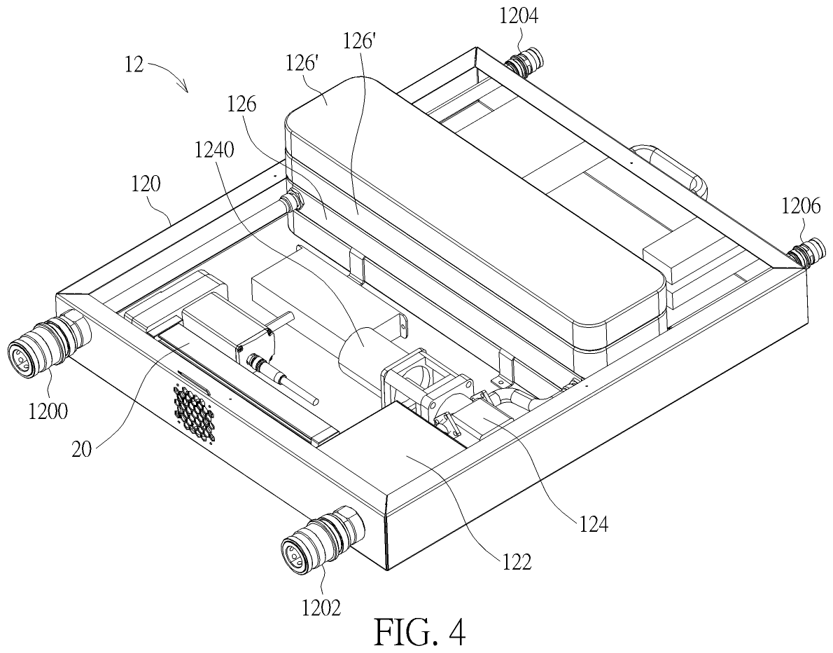

Referring to FIG. 4, FIG. 4 is a perspective view illustrating the liquid cooling device 12 according to another embodiment of the disclosure.

As shown in FIG. 4, in another embodiment, the liquid cooling device 12 may further comprise an another heat exchanger 126′, wherein the another heat exchanger 126′ is stacked and communicates with the heat exchanger 126. It should be noted that the another heat exchanger 126′ may be determined according to practical applications, so the disclosure is not limited to the embodiment shown in the figure. Therefore, the disclosure may adjust the number of heat exchangers according to practical heat dissipation requirements.

As mentioned in the above, the disclosure utilizes the first inlet, the heat exchanger, the first pump, the first tank and the first outlet to form the first cooling loop in the casing of the liquid cooling device, and utilizes the second inlet, the heat exchanger and the second outlet to form the second cooling loop in the casing. Accordingly, the cooling liquid in the first cooling loop may be oil, dielectric liquid or the like with higher cost, and the cooling liquid in the second cooling loop may be water or the like with lower cost. The cooling liquid in the first cooling loop exchanges heat through the heat exchanger. Thus, the cooling liquid in the first cooling loop does not need to be transported to an external cooling distribution unit through a manifold for heat exchange. Accordingly, the disclosure can save the amount of cooling liquid in the manifold and the external cooling distribution unit, such that the liquid cooling device of the disclosure can effectively reduce the amount of high-cost cooling liquid in the first cooling loop.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A cooling system comprising:
an electronic device; and
a liquid cooling device comprising:
a casing;
a first inlet disposed on the casing and connected to the electronic device;
a first outlet disposed on the casing and connected to the electronic device;
a second inlet disposed on the casing;
a second outlet disposed on the casing;
a first tank disposed in the casing;
a first pump disposed in the casing; and
a heat exchanger disposed in the casing;
wherein the first inlet, the heat exchanger, the first pump, the first tank and the first outlet form a first cooling loop in the casing, the second inlet, the heat exchanger and the second outlet form a second cooling loop in the casing, and the heat exchanger is located between the first cooling loop and the second cooling loop.

2. The cooling system of claim 1, wherein the first tank is connected to the first outlet, the first pump is connected to the first tank, the heat exchanger is connected to the first pump and the first inlet, and the heat exchanger is connected to the second inlet and the second outlet.

3. The cooling system of claim 1, further comprising a cooling distribution unit, wherein the cooling distribution unit is located outside the casing, and the second inlet and the second outlet are connected to the cooling distribution unit.

4. The cooling system of claim 1, wherein a cooling liquid in the first cooling loop is different from a cooling liquid in the second cooling loop.

5. The cooling system of claim 4, wherein the cooling liquid in the first cooling loop is a dielectric liquid, and the cooling liquid in the second cooling loop is water.

6. The cooling system of claim 2, further comprising a cooling distribution unit, wherein the cooling distribution unit is located outside the casing, the second inlet and the second outlet are connected to the cooling distribution unit, a cooling liquid in the first cooling loop is a dielectric liquid, and a cooling liquid in the second cooling loop is water.

7. The cooling system of claim 1, wherein the first tank is connected to the first outlet, the first pump is connected to the first tank, the heat exchanger is connected to the first pump and the first inlet, the liquid cooling device further comprises a second tank and a second pump, the second tank is disposed in the casing and connected to the second outlet, the second pump is disposed in the casing and connected to the second tank, the heat exchanger is connected to the second pump and the second inlet, and the second inlet, the heat exchanger, the second pump, the second tank and the second outlet form the second cooling loop in the casing.

8. The cooling system of claim 7, further comprising a liquid storage device, wherein the liquid storage device is located outside the casing, and the second inlet and the second outlet are connected to the liquid storage device.

9. The cooling system of claim 1, wherein the liquid cooling device further comprises an another heat exchanger, and the another heat exchanger is stacked and communicates with the heat exchanger.

10. The cooling system of claim 1, wherein the liquid cooling device further comprises a temperature sensor, a temperature controller, an electric cylinder and a volume control panel, the temperature sensor is disposed in the first tank, the first pump comprises a motor, the temperature controller is disposed on the casing and coupled to the temperature sensor and the motor, the temperature sensor senses a temperature of a cooling liquid in the first tank, the temperature controller responds to the temperature sensor to control a rotation speed of the motor to regulate the temperature of the cooling liquid, the electric cylinder is connected to the first tank, the volume control panel is disposed on the casing and coupled to the electric cylinder, and the volume control panel controls the electric cylinder to regulate a liquid level of a cooling liquid in the first tank.

11. A liquid cooling device comprising:
a casing;
a first inlet disposed on the casing;
a first outlet disposed on the casing;
a second inlet disposed on the casing;
a second outlet disposed on the casing;
a first tank disposed in the casing;
a first pump disposed in the casing; and
a heat exchanger disposed in the casing;
wherein the first inlet, the heat exchanger, the first pump, the first tank and the first outlet form a first cooling loop in the casing, the second inlet, the heat exchanger and the second outlet form a second cooling loop in the casing, and the heat exchanger is located between the first cooling loop and the second cooling loop.

12. The liquid cooling device of claim 11, wherein the first tank is connected to the first outlet, the first pump is connected to the first tank, the heat exchanger is connected to the first pump and the first inlet, and the heat exchanger is connected to the second inlet and the second outlet.

13. The liquid cooling device of claim 11, wherein the first inlet and the first outlet are connected to an electronic device, the second inlet and the second outlet are connected to a cooling distribution unit, and the electronic device and the cooling distribution unit are located outside the casing.

14. The liquid cooling device of claim 11, wherein a cooling liquid in the first cooling loop is different from a cooling liquid in the second cooling loop.

15. The liquid cooling device of claim 14, wherein the cooling liquid in the first cooling loop is a dielectric liquid, and the cooling liquid in the second cooling loop is water.

16. The liquid cooling device of claim 12, wherein the first inlet and the first outlet are connected to an electronic device, the second inlet and the second outlet are connected to a cooling distribution unit, the electronic device and the cooling distribution unit are located outside the casing, a cooling liquid in the first cooling loop is a dielectric liquid, and a cooling liquid in the second cooling loop is water.

17. The liquid cooling device of claim 11, wherein the first tank is connected to the first outlet, the first pump is connected to the first tank, the heat exchanger is connected to the first pump and the first inlet, the liquid cooling device further comprises a second tank and a second pump, the second tank is disposed in the casing and connected to the second outlet, the second pump is disposed in the casing and connected to the second tank, the heat exchanger is connected to the second pump and the second inlet, and the second inlet, the heat exchanger, the second pump, the second tank and the second outlet form the second cooling loop in the casing.

18. The liquid cooling device of claim 17, wherein the first inlet and the first outlet are connected to an electronic device, the second inlet and the second outlet are connected to a liquid storage device, and the electronic device and the liquid storage device are located outside the casing.

19. The liquid cooling device of claim 11, wherein the liquid cooling device further comprises another heat exchanger, and the another heat exchanger is stacked and communicates with the heat exchanger.

20. The liquid cooling device of claim 11, wherein the liquid cooling device further comprises a temperature sensor, a temperature controller, an electric cylinder and a volume control panel, the temperature sensor is disposed in the first tank, the first pump comprises a motor, the temperature controller is disposed on the casing and coupled to the temperature sensor and the motor, the temperature sensor senses a temperature of a cooling liquid in the first tank, the temperature controller responds to the temperature sensor to control a rotation speed of the motor to regulate the temperature of the cooling liquid, the electric cylinder is connected to the first tank, the volume control panel is disposed on the casing and coupled to the electric cylinder, and the volume control panel controls the electric cylinder to regulate a liquid level of a cooling liquid in the first tank.
